(19) United States
(12) Patent Application Publication
(10) Pub. No.: US 2025/0078912 A1
(43) Pub. Date: Mar. 6, 2025

(54) Multi-Transistor Bitcell Structure

(71) Applicant: Arm Limited, Cambridge (GB)

(72) Inventors: Andy Wangkun Chen, Austin, TX (US); Rahul Mathur, Austin, TX (US)

(21) Appl. No.: 18/240,875

(22) Filed: Aug. 31, 2023

(51) Int. Cl. G11C 11/412; G11C 11/419; H10B 10/00

(52) U.S. Cl. CPC G11C 11/412; G11C 11/419; H10B 10/12

(57) ABSTRACT

Various implementations described herein are directed to a device having first transistors arranged as cross-coupled inverters coupled between a disconnect node and ground. The device may have second transistors arranged as passgates coupled between the cross-coupled inverters and bitlines. The device may have third transistors coupled between a voltage supply and the disconnect node.

### BACKGROUND

This section is intended to provide information relevant to understanding the various technologies described herein. As the section's title implies, this is a discussion of related art that should in no way imply that it is prior art. Generally, related art may or may not be considered prior art. It should therefore be understood that any statement in this section should be read in this light, and not as any admission of prior art.

In some modern circuit architectures, deficiencies can arise when implementing write assist schemes to improve the writability of a bitcell in common memory applications, such as static random access memory (SRAM) applications. For instance, some common write assist schemes use a negative bitline (NBL) and transient voltage collapse (TVC) to provide write assist to a bitcell. However, these common write assist schemes may suffer from shortcomings in that area of memory is increased to implement write-assist circuitry, and also, dynamic power and/or delay of a write operation are increased due to an extra step of a write assist operation. Also, other shortcomings refer to a decrease in reliability of a bitcell in the case of an excessive NBL level, and other shortcomings refer to circuitry that needs fine-tuning for process variability and operating condition range for a range of rows-per-bitline options. Thus, there exists a need for more efficient bitcell designs that reduce area inefficiencies, improve integration schemes and enhance dynamic power by providing more effective write assist schemes for memory based applications.

### BRIEF DESCRIPTION OF THE DRAWINGS

Implementations of various techniques are described herein with reference to the accompanying drawings. It should be understood, however, that the accompanying drawings illustrate only various implementations described herein and are not meant to limit embodiments of various techniques described herein.

FIGS. 1A-1B illustrate diagrams of bitcell architecture in a first configuration in accordance with various implementations described herein.

FIGS. 2A-2B illustrate diagrams of bitcell architecture in a second configuration in accordance with various implementations described herein.

FIGS. 3A-3B illustrate diagrams of bitcell architecture in a third configuration in accordance with various implementations described herein.

FIGS. 4A-4B illustrate diagrams of bitcell architecture in a fourth configuration in accordance with various implementations described herein.

FIG. 5 illustrates a diagram of a transistor layout for a bitcell architecture in accordance with various implementations described herein.

### DETAILED DESCRIPTION

Various implementations described herein are directed to multi-transistor bitcell schemes and techniques for various circuit related applications in physical designs. Also, in some implementations, the multi-transistor bitcell schemes and techniques described herein provide for CFET (complementary field effect transistor) SRAM bitcell designs with built-in write assist feature that improves area and performance of memory. Also, in some implementations, the multi-transistor bitcell schemes and techniques described herein provide for buried conductive lines, such as, e.g., buried wordlines, buried bitlines, buried power lines, buried control lines, etc., that also improve area and performance of memory in some memory based applications, such as, e.g., SRAM, and/or similar.

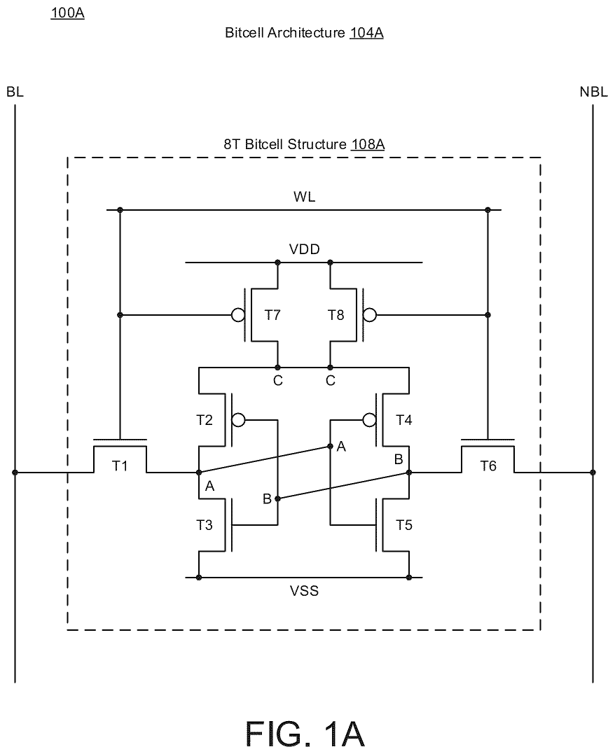

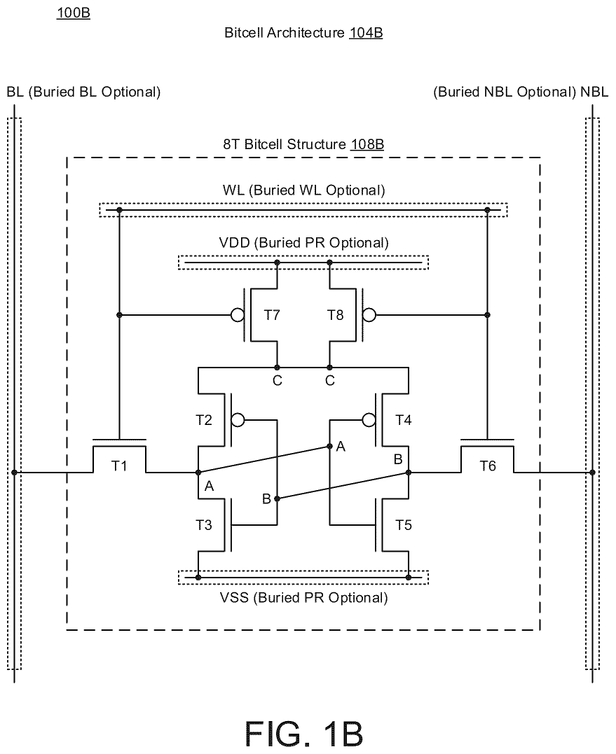

Various implementations of multi-transistor bitcell schemes and techniques for memory based applications will now be described herein in FIGS. 1A-1B to 4A-4B.

FIGS. 1A-1B illustrate various diagrams of bitcell architectures 104A, 104B in a first configuration in accordance with implementations described herein. In particular, FIG. 1A shows a schematic diagram 100A of the bitcell architecture 104A in the first configuration, and FIG. 1B shows a schematic diagram 100B of the bitcell architecture 104B in the first configuration with various optional buried lines.

In some implementations, the bitcell architectures 104A, 104B may provide for fabricating multi-transistor bitcell related memory circuitry with various integrated circuit (IC) components that are arranged and/or coupled together as an assemblage or some combination of parts that may provide for physical circuit designs and structures. In some instances, a method of designing, providing and fabricating the bitcell architectures 104A, 104B as an integrated device may involve use of various circuit components and related structures described herein so as to implement various multi-transistor bitcell techniques associated therewith. Also, the bitcell architectures 104A, 104B may be integrated with various circuitry and/or related components on a single chip, and the bitcell architectures 104A, 104B may be implemented in some embedded devices for automotive, mobile, computer, server and/or Internet-of-Things (IoT) based applications.

As shown in FIG. 1A, the bitcell architecture 104A may include a plurality of transistors (e.g., T1, T2, . . . , T8), including, e.g., first transistors (T2, T3, T4, T5), second transistors (T1, T6) and third transistors (T7, T8), that are arranged and coupled together to operate as a multi-transistor bitcell structure, such as, e.g., an 8-transistor (8T) bitcell structure for various memory based applications. In some instances, the first transistors (T2, T3, T4, T5) may be arranged as cross-coupled inverters (T2/T3 and T4/T5) coupled between a disconnect node (C) and ground (VSS or GND). Also, the second transistors (T1, T6) may be arranged and coupled as passgates coupled between the corresponding cross-coupled inverters (T2/T3 and T4/T5) and complementary bitlines (BL, NBL). Also, in some instances, the third transistors (T7, T8) may be coupled between a voltage supply (VDD) and disconnect node (C).

In some implementations, the first transistors (T2, T3, T4, T5) and the second transistors (T1, T6) may be configured to operate as a cross-coupled bitcell latch, and the third transistors (T7, T8) may be configured to provide a write assist feature for the cross-coupled bitcell latch that operates to disconnect the cross-coupled bitcell latch from the voltage supply (VDD) when deactivated by a wordline signal on the wordline (WL), which may be referred to as a write wordline. Also, in some implementations, the wordline (WL) may be coupled to the gates of the second transistors (T1, T6) and the third transistors (T7, T8), and the write assist feature may operate as a built-in write assist feature when the wordline (WL) is asserted high so as to deactivate the third transistors (T7, T8).

In various implementations, first transistors (T2, T3, T4, T5), second transistors (T1, T6) and third transistors (T7, T8) comprise P-type transistors and N-type transistors, and also, the first transistors (T2, T3, T4, T5), the second transistors (T1, T6) and the third transistors (T7, T8) may be formed with a P-type and N-type complementary field effect transistor (PN CFET) technology such that the P-type transistors are physically disposed on the N-type transistors or such that the N-type transistors are physically disposed on the P-type transistors. Also, in various instances, transistors (T2, T4, T7, T8) may be P-type transistors, and transistors (T1, T3, T5, T6) may be N-type transistors, wherein T7 may be physically disposed on T1, and T8 may be physically disposed on T6, and T2 may be physically disposed on T3, and also, T4 may be physically disposed on T5, in various memory based applications. However, various other configurations may be used and/or implemented to achieve similar results and/or behavior, wherein in some instances, the N-type transistors are physically disposed on the P-type transistors.

As shown in FIG. 1A, the bitcell architecture 104A may be implemented with a multi-transistor bitcell structure, such as, e.g., 8T bitcell related structure 108A. In some implementations, the multi-transistor bitcell structure 108A may be configured as a multi-transistor (e.g., eight-transistor (8T)) single-port SRAM bitcell structure, wherein the eight transistors (8T) may include multiple (e.g., 4) N-type metal-oxide-semiconductor (NMOS) transistors and multiple (e.g., 4) P-type MOS (PMOS) transistors. In some instances, a first passgate transistor (T1) may be coupled between a first bitline (BL) and a node (A), and a second passgate transistor (T6) may be coupled between a second bitline (NBL) and another node (B), wherein the second bitline (NBL) is complementary to the first bitline (BL). Also, the wordline (WL) may be coupled to the gates of transistors (T1, T6) to access data stored in the bitcell latch that is formed with multiple transistors (T2, T3, T4, T5) via the wordline (WL) and complementary bitlines (BL, NBL). Also, in some instances, the wordline (WL) may be coupled to the gates of transistors (T7, T8) so that the write assist feature may operate as the built-in write assist feature when the wordline (WL) is asserted high so as to deactivate the third transistors (T7, T8).

Also, in some implementations, transistors (T2, T3) may be coupled in series between voltage supply (VDD) and ground (VSS or GND), wherein the node (A) is formed between pull-up transistor (T2) and pull-down transistor (T3). Also, transistors (T4, T5) may be coupled in series between the voltage supply (VDD) and ground (VSS or GND), wherein the node (B) is formed between pull-up transistor (T4) and pull-down transistor (T5). Also, transistors (T2, T3) may be cross-coupled with transistors (T4, T5) such that the node (A) is coupled to the gates of transistors (T4, T5) and such that the other node (B) is coupled to gates of transistors (T2, T3). Also, transistors (T7, T8) may be coupled between voltage supply (VDD) and disconnect node (C). In some instances, transistors (T2, T4, T7, T8) may refer to P-type field-effect transistors (PFET), and transistors (T1, T3, T5, T6) refer to N-type FET (NFET) transistors. However, various other configurations may be used to achieve similar results and/or behavior.

As shown in FIG. 1B, the bitcell architecture 104B may have the plurality of transistors (e.g., T1, T2, . . . , T8), including, e.g., first transistors (T2, T3, T4, T5), second transistors (T1, T6) and third transistors (T7, T8), that are arranged and coupled together to operate as a multi-transistor bitcell structure, such as, e.g., an 8-transistor (8T) bitcell structure for various memory based applications. In some instances, the first transistors (T2, T3, T4, T5) may be arranged as cross-coupled inverters (T2/T3 and T4/T5) coupled between a disconnect node (C) and ground (VSS or GND). Also, the second transistors (T1, T6) may be arranged and coupled as passgates coupled between the corresponding cross-coupled inverters (T2/T3 and T4/T5) and complementary bitlines (BL, NBL). Also, in some instances, the third transistors (T7, T8) may be coupled between a voltage supply (VDD) and disconnect node (C).

In various optional implementations, one or more of the conductive lines may be optionally buried within a substrate. For instance, the first transistors (T2, T3, T4, T5), second transistors (T1, T6) and third transistors (T7, T8) may be formed on a substrate, and optionally, in various applications, the wordline (WL) may comprise a buried wordline formed within the substrate. Also, optionally, in various applications, one or more bitlines (BL, NBL) may comprise buried bitlines formed within the substrate.

In various optional implementations, one or more of the conductive power lines may be optionally buried within a substrate. For instance, in various optional applications, the voltage supply (VDD) may be coupled to a first buried power rail (BPR) that is formed within the substrate. Also, optionally, in various optional applications, the ground (VSS or GND) may be coupled to another second buried power rail (BPR) that is formed within the substrate. As such, one or more buried power rails (BPRs) may be formed in the substrate for voltage supply (VDD) and/or ground (VSS or GND) in memory based applications so as to improve area and performance of the cross-coupled bitcell structure 108B.

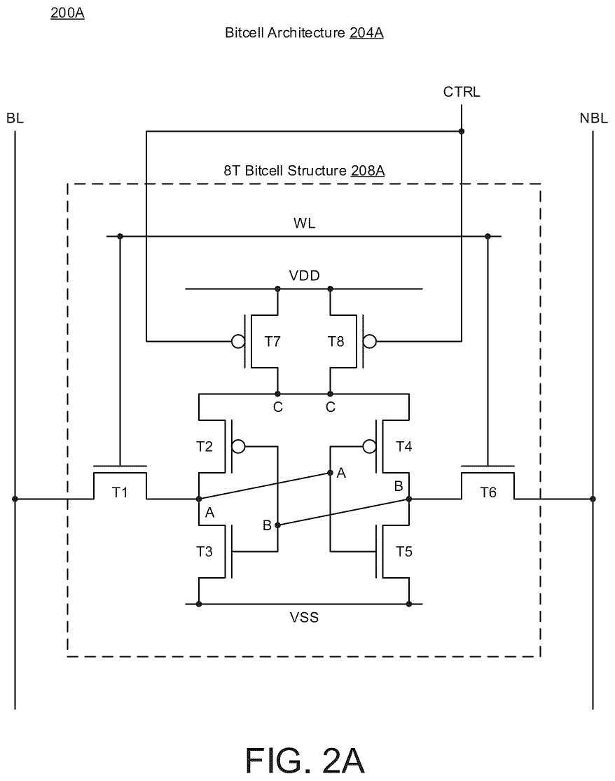

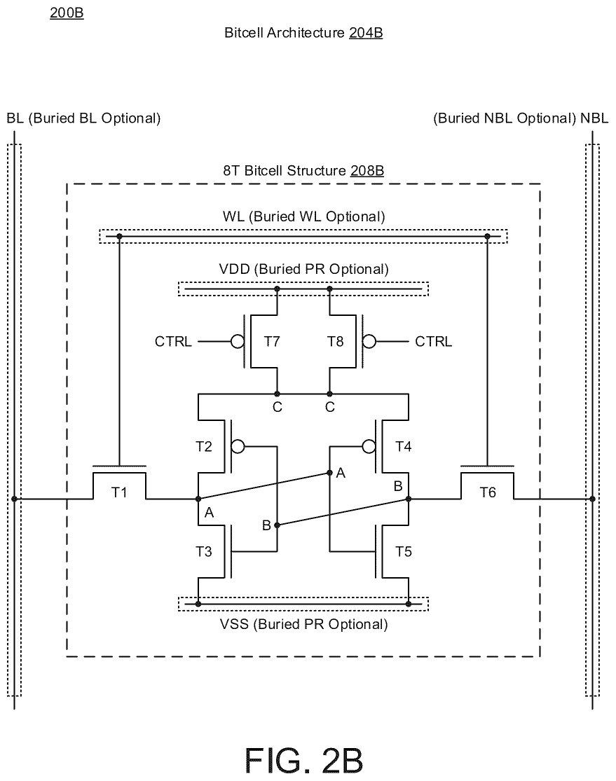

FIGS. 2A-2B illustrate diagrams of bitcell architecture 204A, 204B in a second configuration in accordance with various implementations described herein. In particular, FIG. 2A shows a schematic diagram 200A of the bitcell architecture 204A in the second configuration, and FIG. 2B shows a schematic diagram 200B of the bitcell architecture 204B in the second configuration with various optional buried lines.

In some implementations, the bitcell architectures 204A, 204B may provide for fabricating multi-transistor bitcell related memory circuitry with various integrated circuit (IC) components that are arranged and/or coupled together as an assemblage or some combination of parts that may provide for physical circuit designs and structures. In some instances, a method of designing, providing and fabricating the bitcell architectures 204A, 204B as an integrated device may involve use of various circuit components and related structures described herein so as to implement various multi-transistor bitcell techniques associated therewith. Also, the bitcell architectures 204A, 204B may be integrated with various circuitry and/or related components on a single chip, and the bitcell architectures 204A, 204B may be implemented in some embedded devices for automotive, mobile, computer, server and/or Internet-of-Things (IoT) based applications.

As shown in FIG. 2A, the bitcell architecture 204A may include a plurality of transistors (e.g., T1, T2, . . . , T8), including, e.g., first transistors (T2, T3, T4, T5), second transistors (T1, T6) and third transistors (T7, T8), that are arranged and coupled together to operate as a multi-transistor bitcell structure, such as, e.g., an 8-transistor (8T) bitcell structure for various memory based applications. In some instances, the first transistors (T2, T3, T4, T5) may be arranged as cross-coupled inverters (T2/T3 and T4/T5) coupled between a disconnect node (C) and ground (VSS or GND). Also, the second transistors (T1, T6) may be arranged and coupled as passgates coupled between the corresponding cross-coupled inverters (T2/T3 and T4/T5) and complementary bitlines (BL, NBL). Also, in some instances, the third transistors (T7, T8) may be coupled between a voltage supply (VDD) and disconnect node (C).

In some implementations, the first transistors (T2, T3, T4, T5) and the second transistors (T1, T6) may be configured to operate as a cross-coupled bitcell latch, and the third transistors (T7, T8) may be configured to provide a write assist feature for the cross-coupled bitcell latch that operates to disconnect the cross-coupled bitcell latch from the voltage supply (VDD) when deactivated by a control signal (or similar signal) on a control-line (CTRL). Also, in various implementations, the wordline (WL) may be coupled to the gates of the second transistors (T1, T6), and also, the write assist feature may operate as a built-in write assist feature when the control-line (CTRL) is asserted high so as to thereby deactivate the third transistors (T7, T8). Thus, the control-line (CTRL) may be coupled to gates of the third transistors (T7, T8), and the write assist feature operates as the built-in write assist feature when the control-line (CTRL) is asserted high so as to deactivate the third transistors (T7, T8), e.g., when the wordline (WL) is also asserted high. As described herein, the wordline (WL) may be referred to as a write wordline.

In various implementations, first transistors (T2, T3, T4, T5), second transistors (T1, T6) and third transistors (T7, T8) comprise P-type transistors and N-type transistors, and also, the first transistors (T2, T3, T4, T5), the second transistors (T1, T6) and the third transistors (T7, T8) may be formed with a P-type and N-type complementary field effect transistor (PN CFET) technology such that the P-type transistors are physically disposed on the N-type transistors, or such that the N-type transistors are physically disposed on the P-type transistors. Also, in various instances, transistors (T2, T4, T7, T8) may be P-type transistors, and transistors (T1, T3, T5, T6) may be N-type transistors, wherein T7 may be physically disposed on T1, and T8 may be physically disposed on T6, and T2 may be physically disposed on T3, and also, T4 may be physically disposed on T5, in various memory based applications. However, various other configurations may be used and/or implemented to achieve similar results and/or behavior, wherein in some instances, the N-type transistors are physically disposed on the P-type transistors.

As shown in FIG. 2A, the bitcell architecture 204A may be implemented with a multi-transistor bitcell structure, such as, e.g., 8T bitcell related structure 208A. In some implementations, the multi-transistor bitcell structure 208A may be configured as a multi-transistor (e.g., eight-transistor (8T)) single-port SRAM bitcell structure, wherein the eight transistors (8T) may include multiple (e.g., 4) N-type metal-oxide-semiconductor (NMOS) transistors and multiple (e.g., 4) P-type MOS (PMOS) transistors. In some instances, a first passgate transistor (T1) may be coupled between a first bitline (BL) and a node (A), and a second passgate transistor (T6) may be coupled between a second bitline (NBL) and another node (B), wherein the second bitline (NBL) is complementary to the first bitline (BL). Also, the wordline (WL) may be coupled to the gates of transistors (T1, T6) to access data stored in the bitcell latch that is formed with multiple transistors (T2, T3, T4, T5) via the wordline (WL) and complementary bitlines (BL, NBL). Also, in some instances, the control-line (CTRL) may be coupled to the gates of transistors (T7, T8) so that the write assist feature may operate as the built-in write assist feature when the control-line (CTRL) is asserted high so as to deactivate the third transistors (T7, T8).

Also, in some implementations, transistors (T2, T3) may be coupled in series between voltage supply (VDD) and ground (VSS or GND), wherein the node (A) is formed between pull-up transistor (T2) and pull-down transistor (T3). Also, transistors (T4, T5) may be coupled in series between the voltage supply (VDD) and ground (VSS or GND), wherein the node (B) is formed between pull-up transistor (T4) and pull-down transistor (T5). Also, transistors (T2, T3) may be cross-coupled with transistors (T4, T5) such that the node (A) is coupled to the gates of transistors (T4, T5) and such that the other node (B) is coupled to gates of transistors (T2, T3). Also, transistors (T7, T8) may be coupled between voltage supply (VDD) and disconnect node (C). In some instances, transistors (T2, T4, T7, T8) may refer to P-type field-effect transistors (PFET), and transistors (T1, T3, T5, T6) refer to N-type FET (NFET) transistors. However, various other configurations may be used to achieve similar results and/or behavior.

As shown in FIG. 2B, the bitcell architecture 204B may have the plurality of transistors (e.g., T1, T2, . . . , T8), including, e.g., first transistors (T2, T3, T4, T5), second transistors (T1, T6) and third transistors (T7, T8), that are arranged and coupled together to operate as a multi-transistor bitcell structure, such as, e.g., an 8-transistor (8T) bitcell structure for various memory based applications. In some instances, the first transistors (T2, T3, T4, T5) may be arranged as cross-coupled inverters (T2/T3 and T4/T5) coupled between a disconnect node (C) and ground (VSS or GND). Also, the second transistors (T1, T6) may be arranged and coupled as passgates coupled between the corresponding cross-coupled inverters (T2/T3 and T4/T5) and complementary bitlines (BL, NBL). Also, in some instances, the third transistors (T7, T8) may be coupled between a voltage supply (VDD) and disconnect node (C).

In various optional implementations, one or more of the conductive lines may be optionally buried within a substrate. For instance, the first transistors (T2, T3, T4, T5), second transistors (T1, T6) and third transistors (T7, T8) may be formed on a substrate, and optionally, in various applications, the wordline (WL) may comprise a buried wordline formed within the substrate. Also, optionally, in various applications, one or more bitlines (BL, NBL) may comprise buried bitlines formed within the substrate. Also, optionally, in various applications, the control-line (CTRL) and/or conductive lines related thereto may comprise a buried control-line formed within the substrate.

In various optional implementations, one or more of the conductive power lines may be optionally buried within a substrate. For instance, in various optional applications, the voltage supply (VDD) may be coupled to a first buried power rail (BPR) that is formed within the substrate. Also, optionally, in various optional applications, the ground (VSS or GND) may be coupled to another second buried power rail (BPR) that is formed within the substrate. As such, one or more buried power rails (BPRs) may be formed in the substrate for voltage supply (VDD) and/or ground (VSS or GND) in memory based applications so as to improve area and performance of the cross-coupled bitcell structure 208B.

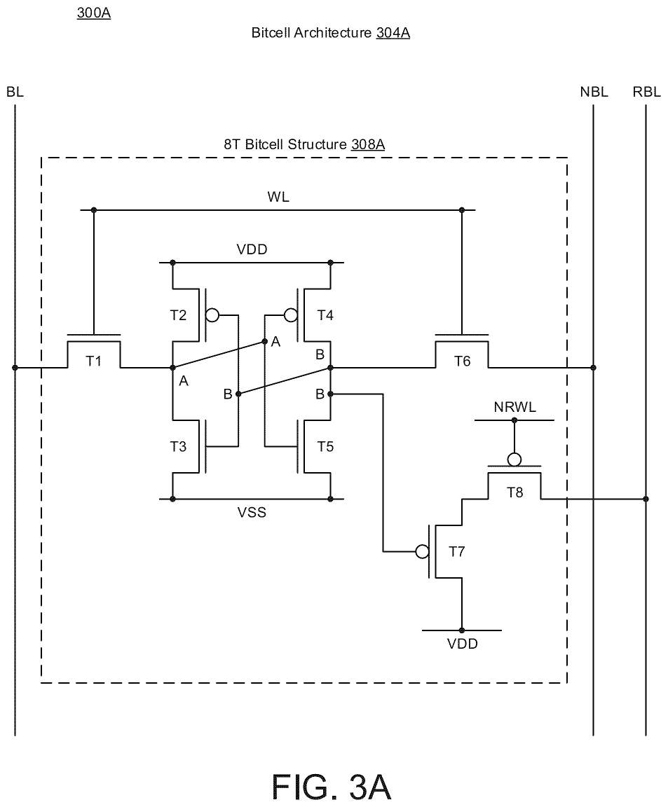

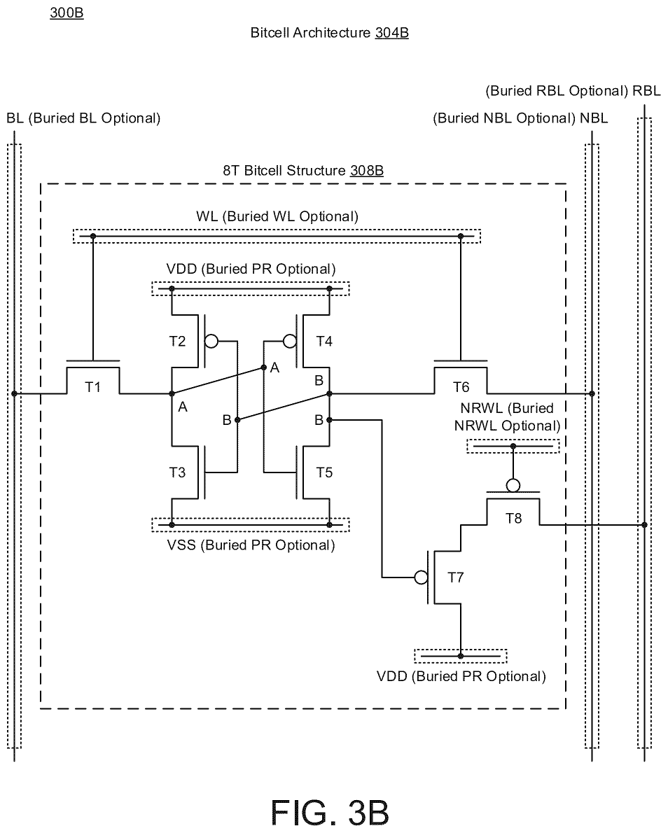

FIGS. 3A-3B illustrate diagrams of bitcell architecture 304A, 304B in a third configuration in accordance with various implementations described herein. In particular, FIG. 3A shows a schematic diagram 300A of the bitcell architecture 304A in the third configuration, and FIG. 3B shows a schematic diagram 300B of the bitcell architecture 304B in the third configuration with various optional buried lines.

In some implementations, the bitcell architectures 304A, 304B may provide for fabricating multi-transistor bitcell related memory circuitry with various integrated circuit (IC) components that are arranged and/or coupled together as an assemblage or some combination of parts that may provide for physical circuit designs and structures. In some instances, a method of designing, providing and fabricating the bitcell architectures 304A, 304B as an integrated device may involve use of various circuit components and related structures described herein so as to implement various multi-transistor bitcell techniques associated therewith. Also, the bitcell architectures 304A, 304B may be integrated with various circuitry and/or related components on a single chip, and the bitcell architectures 304A, 304B may be implemented in some embedded devices for automotive, mobile, computer, server and/or Internet-of-Things (IoT) based applications.

As shown in FIG. 3A, the bitcell architecture 304A may include a plurality of transistors (e.g., T1, T2, . . . , T8), including, e.g., first transistors (T2, T3, T4, T5), second transistors (T1, T6) and third transistors (T7, T8), that are arranged and coupled together to operate as a multi-transistor bitcell structure, such as, e.g., an 8-transistor (8T) bitcell structure for various memory based applications. In some instances, the first transistors (T2, T3, T4, T5) may be arranged as cross-coupled inverters (T2/T3 and T4/T5) coupled between a disconnect node (C) and ground (VSS or GND). Also, the second transistors (T1, T6) may be arranged and coupled as passgates coupled between the corresponding cross-coupled inverters (T2/T3 and T4/T5) and complementary bitlines (BL, NBL). Also, in some instances, the third transistors (T7, T8) may be coupled in series between voltage supply (VDD) and a read bitline (RBL).

In some implementations, the first transistors (T2, T3, T4, T5) and the second transistors (T1, T6) may be configured to operate as a cross-coupled bitcell latch, and the third transistors (T7, T8) are configured to provide a read port for the cross-coupled bitcell latch when a read wordline (RNWL) is activated. Also, the wordline (WL) may be coupled to the gates of the second transistors (T1, T6), and also, the gate of third transistor (T7) may be coupled to node (B), and also, the gate of third transistor (T8) may be coupled to the read wordline (NRWL). Accordingly, the third transistors (T7, T8) may be configured to provide the read port to the cross-coupled bitcell latch by way of the read bitline (RBL) for when the read wordline (NRWL) is activated.

In various implementations, first transistors (T2, T3, T4, T5), second transistors (T1, T6) and third transistors (T7, T8) comprise P-type transistors and N-type transistors, and also, the first transistors (T2, T3, T4, T5), the second transistors (T1, T6) and the third transistors (T7, T8) may be formed with a P-type and N-type complementary field effect transistor (PN CFET) technology such that the P-type transistors are physically disposed on the N-type transistors, or such that the N-type transistors are physically disposed on the P-type transistors. Also, in various instances, transistors (T2, T4, T7, T8) may be P-type transistors, and transistors (T1, T3, T5, T6) may be N-type transistors, wherein T7 may be physically disposed on T1, and T8 may be physically disposed on T6, and T2 may be physically disposed on T3, and also, T4 may be physically disposed on T5, in various memory based applications. However, various other configurations may be used and/or implemented to achieve similar results and/or behavior, wherein in some instances, or such that the N-type transistors are physically disposed on the P-type transistors.

As shown in FIG. 3A, the bitcell architecture 304A may be implemented with a multi-transistor bitcell structure, such as, e.g., 8T bitcell related structure 308A. In some implementations, the multi-transistor bitcell structure 308A may be configured as a multi-transistor (e.g., eight-transistor (8T)) single-port SRAM bitcell structure, wherein the eight transistors (8T) may include multiple (e.g., 4) N-type metal-oxide-semiconductor (NMOS) transistors and multiple (e.g., 4) P-type MOS (PMOS) transistors. In some instances, a first passgate transistor (T1) may be coupled between a first bitline (BL) and a node (A), and a second passgate transistor (T6) may be coupled between a second bitline (NBL) and another node (B), wherein the second bitline (NBL) is complementary to the first bitline (BL). Also, the wordline (WL) may be coupled to the gates of transistors (T1, T6) to access data stored in the bitcell latch that is formed with multiple transistors (T2, T3, T4, T5) via the wordline (WL) and complementary bitlines (BL, NBL). Also, in various instances, the node (B) may be coupled to the gate of transistor (T7), and the read wordline (NRWL) may be coupled to the gate of transistor (T8). Also, the third transistors (T7, T8) may be configured to provide the read port for the cross-coupled bitcell latch by way of the read bitline (RBL) when the read wordline (NRWL) is activated.

Also, in some implementations, transistors (T2, T3) may be coupled in series between voltage supply (VDD) and ground (VSS or GND), wherein the node (A) is formed between pull-up transistor (T2) and pull-down transistor (T3). Also, transistors (T4, T5) may be coupled in series between the voltage supply (VDD) and ground (VSS or GND), wherein the node (B) is formed between pull-up transistor (T4) and pull-down transistor (T5). Also, transistors (T2, T3) may be cross-coupled with transistors (T4, T5) such that the node (A) is coupled to the gates of transistors (T4, T5) and such that the other node (B) is coupled to gates of transistors (T2, T3). Also, transistors (T7, T8) may be coupled in series between the voltage supply (VDD) and the read bitline (RBL). In some instances, transistors (T2, T4, T7, T8) may refer to P-type field-effect transistors (PFET), and also, transistors (T1, T3, T5, T6) refer to N-type FET (NFET) transistors. However, various other configurations may be used to achieve similar results and/or behavior.

As shown in FIG. 3B, the bitcell architecture 304B may have the plurality of transistors (e.g., T1, T2, . . . , T8), including, e.g., first transistors (T2, T3, T4, T5), second transistors (T1, T6) and third transistors (T7, T8), that are arranged and coupled together to operate as a multi-transistor bitcell structure, such as, e.g., an 8-transistor (8T) bitcell structure for various memory based applications. In some instances, the first transistors (T2, T3, T4, T5) may be arranged as cross-coupled inverters (T2/T3 and T4/T5) coupled between a disconnect node (C) and ground (VSS or GND). Also, the second transistors (T1, T6) may be arranged and coupled as passgates coupled between the corresponding cross-coupled inverters (T2/T3 and T4/T5) and complementary bitlines (BL, NBL). Also, in some instances, the third transistors (T7, T8) may be coupled in series between voltage supply (VDD) and the read bitline (RBL).

In various optional implementations, one or more of the conductive lines may be optionally buried within a substrate. For instance, the first transistors (T2, T3, T4, T5), second transistors (T1, T6) and third transistors (T7, T8) may be formed on a substrate, and optionally, in various applications, the wordline (WL) may comprise a buried wordline formed within the substrate. Also, optionally, in various applications, one or more bitlines (BL, NBL) may comprise buried bitlines formed within the substrate. Also, optionally, in various applications, the read wordline (NRWL) may comprise a buried read wordline formed within the substrate. Also, the read bitline (RBL) may comprise a buried read bitline formed within the substrate.

In various optional implementations, one or more of the conductive power lines may be optionally buried within a substrate. For instance, in various optional applications, the voltage supply (VDD) may be coupled to a first buried power rail (BPR) that is formed within the substrate. Also, optionally, in various optional applications, the ground (VSS or GND) may be coupled to another second buried power rail (BPR) that is formed within the substrate. As such, one or more buried power rails (BPRs) may be formed in the substrate for voltage supply (VDD) and/or ground (VSS or GND) in memory based applications so as to improve area and performance of the cross-coupled bitcell structure 308B.

Accordingly, in various implementations, in reference to FIGS. 3A-3B, bitcell architectures 304A, 304B may have a plurality of transistors formed with a complementary field effect transistor (CFET) technology such that the P-type transistors are physically disposed on the N-type transistors, or such that the N-type transistors are physically disposed on the P-type transistors. Also, the transistors may include first transistors (T2, T3, T4, T5) that are arranged as cross-coupled inverters (T2/T3, T4/T5) coupled between the voltage supply (VDD) and ground (VSS or GND). Also, the transistors include second transistors (T1, T6) that are arranged as passgates coupled between the cross-coupled inverters (T2/T3, T4/T5) and bitlines (BL, NBL), which may be referred to as write bitlines, in some applications. Also, the transistors may include third transistors (T7, T8) that are coupled in series between the voltage supply (VDD) and the read bitline (RBL). In some applications, the first transistors (T2, T3, T4, T5) and the second transistors (T1, T6) may be configured to operate as a cross-coupled bitcell latch. Also, the gate of one of the third transistors (T7) may be coupled to an output at node (B) of the cross-coupled bitcell latch, and the gate of another of the third transistors (T8) may be coupled to the read wordline (NRWL), and also, the third transistors (T7, T8) may be configured to provide a read port for the cross-coupled bitcell latch when the read wordline (NRWL) is activated.

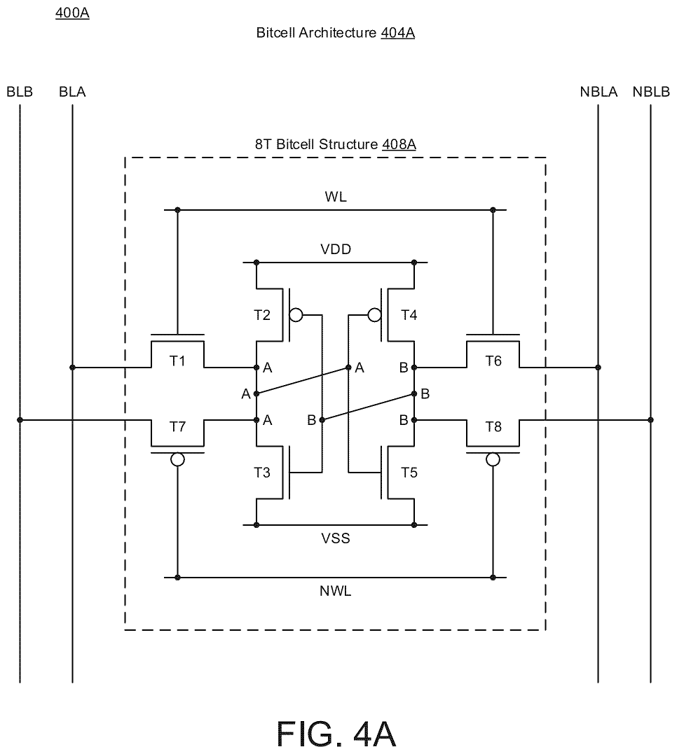

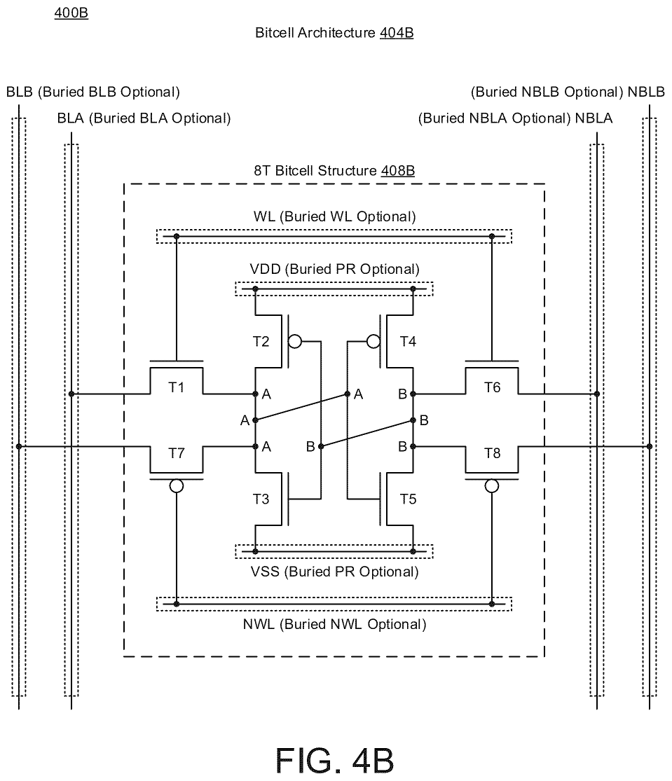

FIGS. 4A-4B illustrate diagrams of bitcell architecture 404A, 404B in a fourth configuration in accordance with various implementations described herein. In particular, FIG. 4A shows a schematic diagram 400A of the bitcell architecture 404A in the fourth configuration, and FIG. 4B shows a schematic diagram 400B of the bitcell architecture 404B in the fourth configuration with various optional buried lines.

In some implementations, the bitcell architectures 404A, 404B may provide for fabricating multi-transistor bitcell related memory circuitry with various integrated circuit (IC) components that are arranged and/or coupled together as an assemblage or some combination of parts that may provide for physical circuit designs and structures. In some instances, a method of designing, providing and fabricating the bitcell architectures 404A, 404B as an integrated device may involve use of various circuit components and related structures described herein so as to implement various multi-transistor bitcell techniques associated therewith. Also, the bitcell architectures 404A, 404B may be integrated with various circuitry and/or related components on a single chip, and the bitcell architectures 404A, 404B may be implemented in some embedded devices for automotive, mobile, computer, server and/or Internet-of-Things (IoT) based applications.

As shown in FIG. 4A, the bitcell architecture 404A may include a plurality of transistors (e.g., T1, T2, . . . , T8), including, e.g., first transistors (T2, T3, T4, T5), second transistors (T1, T6) and third transistors (T7, T8), that are arranged and coupled together to operate as a multi-transistor bitcell structure, such as, e.g., an 8-transistor (8T) bitcell structure for various memory based applications. In some instances, the first transistors (T2, T3, T4, T5) may be arranged as cross-coupled inverters (T2/T3 and T4/T5) coupled between voltage supply (VDD) and ground (VSS or GND). Also, the second transistors (T1, T6) are arranged and coupled as first passgates coupled between the corresponding cross-coupled inverters (T2/T3 and T4/T5) and first complementary bitlines (BL, NBL). Also, the third transistors (T7, T8) are arranged and coupled as second passgates coupled between the corresponding cross-coupled inverters (T2/T3 and T4/T5) and second complementary bitlines (BLB, NBLB).

In various implementations, the first transistors (T2, T3, T4, T5), the second transistors (T1, T6) and the third transistors (T7, T8) may be configured to operate as a cross-coupled bitcell latch having dual-port applications. Also, a first wordline (WL) may be coupled to the gates of the second transistors (T1, T6), and also, a second wordline (NWL) may be coupled to the gates of the third transistors (T7, T8).

In various implementations, first transistors (T2, T3, T4, T5), second transistors (T1, T6) and third transistors (T7, T8) comprise P-type transistors and N-type transistors, and also, the first transistors (T2, T3, T4, T5), the second transistors (T1, T6) and the third transistors (T7, T8) may be formed with a P-type and N-type complementary field effect transistor (PN CFET) technology such that the P-type transistors are physically disposed on the N-type transistors, or such that the N-type transistors are physically disposed on the P-type transistors. Also, in various instances, transistors (T2, T4, T7, T8) may be P-type transistors, and transistors (T1, T3, T5, T6) may be N-type transistors, wherein T7 may be physically disposed on T1, and T8 may be physically disposed on T6, and T2 may be physically disposed on T3, and also, T4 may be physically disposed on T5, in various memory based applications. However, various other configurations may be used and/or implemented to achieve similar results and/or behavior, wherein in some instances, the N-type transistors are physically disposed on the P-type transistors.

As shown in FIG. 4A, the bitcell architecture 404A may be implemented with a multi-transistor bitcell structure, such as, e.g., 8T bitcell related structure 408A. In some implementations, the multi-transistor bitcell structure 408A may be configured as a multi-transistor (e.g., eight-transistor (8T)) single-port SRAM bitcell structure, wherein the eight transistors (8T) may include multiple (e.g., 4) N-type metal-oxide-semiconductor (NMOS) transistors and multiple (e.g., 4) P-type MOS (PMOS) transistors. In some instances, a first passgate transistor (T1) may be coupled between a first bitline (BLA) and a node (A), and a second passgate transistor (T6) may be coupled between a second bitline (NBLA) and a node (B), wherein the second bitline (NBLA) is complementary to the first bitline (BLA). Also, in some instances, a third passgate transistor (T7) may be coupled between a third bitline (BLB) and node (A), and a fourth passgate transistor (T8) may be coupled between a fourth bitline (NBLB) and the node (B), wherein the fourth bitline (NBLB) is complementary to the third bitline (BLB).

Also, the first wordline (WL) may be coupled to the gates of transistors (T1, T6) to access data stored in the bitcell latch that is formed with multiple transistors (T2, T3, T4, T5) via the first wordline (WL) and complementary bitlines (BLA, NBLA). Also, the second wordline (NWL) may be coupled to the gates of transistors (T7, T8) to access data stored in the bitcell latch that is formed with multiple transistors (T2, T3, T4, T5) via the second wordline (NWL) and complementary bitlines (BLB, NBLB).

Also, in some implementations, transistors (T2, T3) may be coupled in series between voltage supply (VDD) and ground (VSS or GND), wherein the node (A) is formed between pull-up transistor (T2) and pull-down transistor (T3). Also, transistors (T4, T5) may be coupled in series between the voltage supply (VDD) and ground (VSS or GND), wherein the node (B) is formed between pull-up transistor (T4) and pull-down transistor (T5). Also, transistors (T2, T3) may be cross-coupled with transistors (T4, T5) such that the node (A) is coupled to the gates of transistors (T4, T5) and such that the other node (B) is coupled to gates of transistors (T2, T3). In some instances, transistors (T2, T4, T7, T8) may refer to P-type field-effect transistors (PFET), and transistors (T1, T3, T5, T6) refer to N-type FET (NFET) transistors. However, various other configurations may also be used to achieve similar results and/or behavior.

As shown in FIG. 4B, the bitcell architecture 404B may have the plurality of transistors (e.g., T1, T2, . . . , T8), including, e.g., first transistors (T2, T3, T4, T5), second transistors (T1, T6) and third transistors (T7, T8), that are arranged and coupled together to operate as a multi-transistor bitcell structure, such as, e.g., an 8-transistor (8T) bitcell structure for various memory based applications. In some instances, the first transistors (T2, T3, T4, T5) may be arranged as cross-coupled inverters (T2/T3 and T4/T5) coupled between voltage supply (VDD) and ground (VSS or GND). Also, the second transistors (T1, T6) may be arranged and coupled as first passgates coupled between corresponding cross-coupled inverters (T2/T3 and T4/T5) and first complementary bitlines (BLA, NBLA). Also, the third transistors (T7, T8) may be arranged and coupled as second passgates coupled between corresponding cross-coupled inverters (T2/T3 and T4/T5) and second complementary bitlines (BLB, NBLB).

In various optional implementations, one or more of the conductive lines may be optionally buried within a substrate. For instance, the first transistors (T2, T3, T4, T5), second transistors (T1, T6) and third transistors (T7, T8) may be formed on a substrate, and optionally, in various applications, the first wordline (WL) may comprise a first buried wordline formed within the substrate, and also, the second wordline (NWL) may comprise a second buried wordline formed within the substrate. Also, optionally, one or more of the bitlines (BL, NBL) may comprise buried bitlines formed within the substrate.

In various optional implementations, one or more of the conductive power lines may be optionally buried within a substrate. For instance, in various optional applications, the voltage supply (VDD) may be coupled to a first buried power rail (BPR) that is formed within the substrate. Also, optionally, in various optional applications, the ground (VSS or GND) may be coupled to another second buried power rail (BPR) that is formed within the substrate. As such, one or more buried power rails (BPRs) may be formed in the substrate for voltage supply (VDD) and/or ground (VSS or GND) in memory based applications so as to improve area and performance of the cross-coupled bitcell structure 408B.

Accordingly, in various implementations, in reference to FIGS. 4A-4B, bitcell architectures 404A,404B may have a plurality of transistors formed with a complementary field effect transistor (CFET) technology such that the P-type transistors are physically disposed on the N-type transistors, or such that the N-type transistors are physically disposed on the P-type transistors. Also, the transistors may include first transistors (T2, T3, T4, T5) that are arranged as cross-coupled inverters (T2/T3, T4/T5) coupled between the voltage supply (VDD) and ground (VSS or GND). Also, the transistors include second transistors (T1, T6) that are arranged as first passgates coupled between cross-coupled inverters (T2/T3, T4/T5) and first bitlines (BLA, NBLA), which may be referred to as first write bitlines in some applications. Also, the transistors include third transistors (T7, T8) that are arranged as second passgates coupled between cross-coupled inverters (T2/T3, T4/T5) and second bitlines (BLB, NBLB), which may be referred to as second write bitlines in some applications.

In some implementations, the gates of the second transistors (T1, T6) may be coupled to the first wordline (WL) such that the second transistors (T1, T6) are configured to provide a first read-write port for the cross-coupled bitcell latch when the first wordline (WL) is activated. Further, in some implementations, the gates of the third transistors (T7, T8) may be coupled to the second wordline (NWL) such that the third transistors (T7, T8) are configured to provide a second read-write port for the cross-coupled bitcell latch when the second wordline (NWL) is activated.

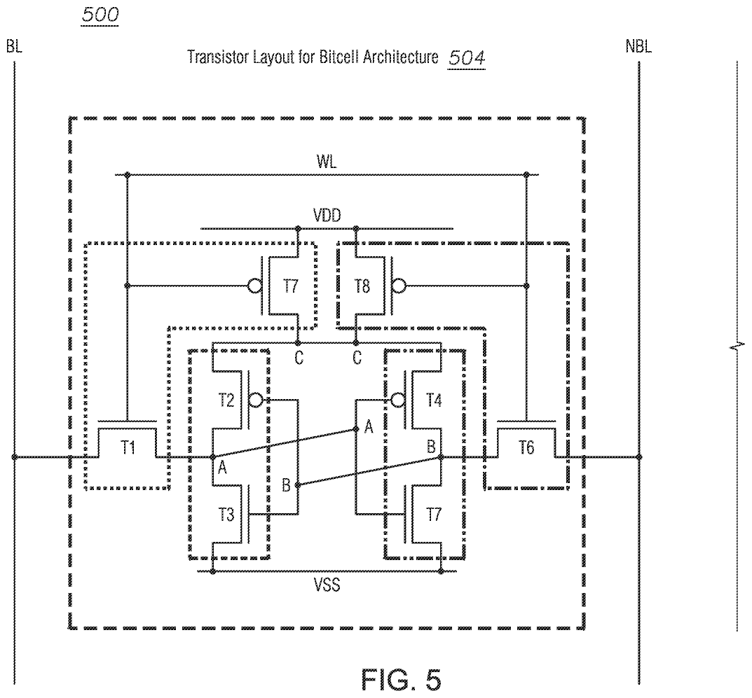

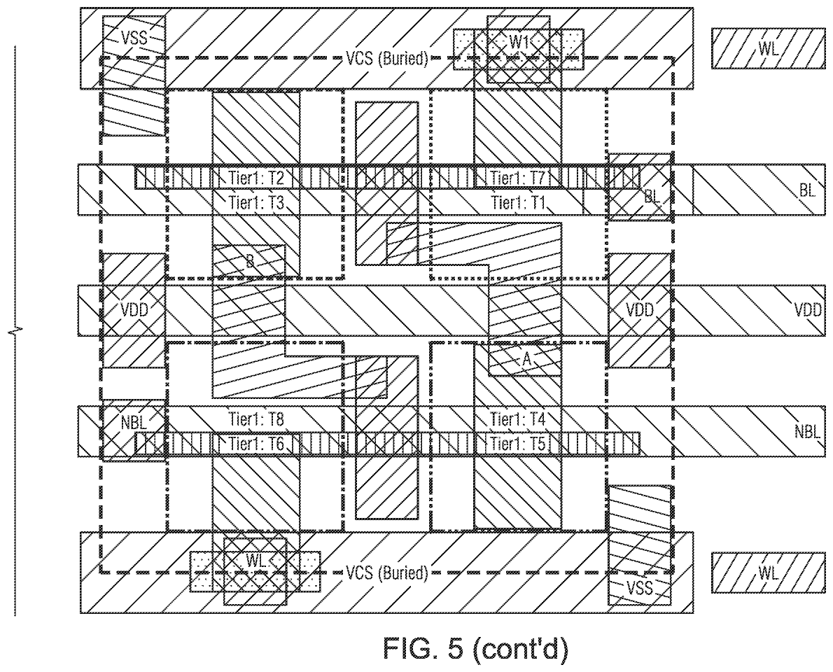

FIG. 5 illustrates a diagram 500 of an example transistor layout for a bitcell architecture 504 in accordance with various implementations described herein. FIG. 5 corresponds to the bitcell structure 108 as shown in FIGS. 1A-1B.

In various implementations, first transistors (T2, T3, T4, T5), second transistors (T1, T6) and third transistors (T7, T8) comprise P-type transistors and N-type transistors, and also, the first transistors (T2, T3, T4, T5), the second transistors (T1, T6) and the third transistors (T7, T8) may be formed with a P-type and N-type complementary field effect transistor (PN CFET) technology such that the P-type transistors are physically disposed on the N-type transistors, or such that the N-type transistors are physically disposed on the P-type transistors. Also, in various instances, transistors (T2, T4, T7, T8) may be P-type transistors, and transistors (T1, T3, T5, T6) may be N-type transistors, wherein T7 may be physically disposed on T1, and T8 may be physically disposed on T6, and T2 may be physically disposed on T3, and also, T4 may be physically disposed on T5, in various memory based applications. However, various other configurations may be used and/or implemented to achieve similar results and/or behavior, wherein in some instances, the N-type transistors are physically disposed on the P-type transistors.

It should be intended that the subject matter of the claims may not be limited to the implementations and illustrations provided herein, but include modified forms of those implementations including portions of implementations and combinations of elements of different implementations in accordance with the claims. It should be appreciated that in the development of any such implementation, as in any engineering or design project, numerous implementation-specific decisions should be made to achieve developers' specific goals, such as compliance with system-related and business related constraints, which may vary from one implementation to another. Moreover, it should be appreciated that such a development effort may be complex and time consuming, but would nevertheless be a routine undertaking of design, fabrication, and manufacture for those of ordinary skill having benefit of this disclosure.

Described herein are various implementations of a device with first transistors arranged as cross-coupled inverters coupled between a disconnect node and ground. The device may have second transistors arranged as passgates coupled between the cross-coupled inverters and bitlines. The device may have third transistors coupled between a voltage supply and the disconnect node.

Described herein are various implementations of a device having a plurality of transistors formed with a complementary field effect transistor (CFET) technology such that P-type transistors are physically disposed on N-type transistors or such that the N-type transistors are physically disposed on the P-type transistors. The transistors may have first transistors arranged as cross-coupled inverters coupled between a voltage supply and ground. The transistors may have second transistors arranged as passgates coupled between the cross-coupled inverters and bitlines. The transistors may have third transistors coupled in series between the voltage supply and a read bitline.

Described herein are various implementations of a device having a plurality of transistors formed with a complementary field effect transistor (CFET) technology such that P-type transistors are physically disposed on N-type transistors or such that the N-type transistors are physically disposed on the P-type transistors. The transistors may have first transistors arranged as cross-coupled inverters coupled between a voltage supply and ground. The transistors may have second transistors arranged as first passgates coupled between the cross-coupled inverters and first bitlines. The transistors may have third transistors arranged as second passgates coupled between the cross-coupled inverters and second bitlines.

Reference has been made in detail to various implementations, examples of which are illustrated in the accompanying drawings and figures. In the following detailed description, numerous specific details are set forth to provide a thorough understanding of the disclosure provided herein. However, the disclosure provided herein may be practiced without these specific details. In some other instances, well-known methods, procedures, components, circuits and networks have not been described in detail so as not to unnecessarily obscure details of the embodiments.

It should also be understood that, although the terms first, second, etc. may be used herein to describe various elements, these elements should not be limited by these terms. These terms are only used to distinguish one element from another. For example, a first element could be termed a second element, and, similarly, a second element could be termed a first element. The first element and the second element are both elements, respectively, but they are not to be considered the same element.

The terminology used in the description of the disclosure provided herein is for the purpose of describing particular implementations and is not intended to limit the disclosure provided herein. As used in the description of the disclosure provided herein and appended claims, the singular forms “a,” “an,” and “the” are intended to include the plural forms as well, unless the context clearly indicates otherwise. The term “and/or” as used herein refers to and encompasses any and all possible combinations of one or more of the associated listed items. The terms “includes,” “including,” “comprises,” and/or “comprising,” when used in this specification, specify a presence of stated features, integers, steps, operations, elements, and/or components, but do not preclude the presence or addition of one or more other features, integers, steps, operations, elements, components and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. The terms “up” and “down”; “upper” and “lower”; “upwardly” and “downwardly”; “below” and “above”; and other similar terms indicating relative positions above or below a given point or element may be used in connection with some implementations of various technologies described herein.

While the foregoing is directed to implementations of various related techniques described herein, other and further implementations may be devised in accordance with the disclosure herein, which may be determined by the claims that follow.

Although the subject matter has been described herein in language specific to structural features and/or methodological acts, it should be understood that the subject matter defined in the appended claims is not necessarily limited to the specific features or acts described above. Rather, specific features and acts described above are disclosed as example forms of implementing the claims.

What is claimed is:

1. A device comprising:
first transistors arranged as cross-coupled inverters coupled between a disconnect node and ground,
second transistors arranged as passgates coupled between the cross-coupled inverters and bitlines; and
third transistors coupled between a voltage supply and the disconnect node.

2. The device of claim 1, wherein:
the first transistors and the second transistors are configured to operate as a cross-coupled bitcell latch, and
the third transistors are configured to provide a write assist feature that disconnects the cross-coupled bitcell latch from the voltage supply when deactivated.

3. The device of claim 2, further comprising:
a wordline coupled to gates of the second transistors and the third transistors,
wherein the write assist feature operates as a built-in write assist feature when the wordline is asserted high so as to deactivate the third transistors.

4. The device of claim 3, wherein:
the first transistors, the second transistors and the third transistors are formed on a substrate, and
the wordline comprises a buried wordline formed within the substrate.

5. The device of claim 2, further comprising:
a wordline coupled to gates of the second transistors; and
a control-line coupled to gates of the third transistors,
wherein the write assist feature operates as a built-in write assist feature when the control-line is asserted high so as to deactivate the third transistors.

6. The device of claim 5, wherein:
the first transistors, the second transistors and the third transistors are formed on a substrate, and
the wordline comprises a buried wordline formed within the substrate.

7. The device of claim 1, wherein:
the first transistors, the second transistors and the third transistors are formed on a substrate, and
the bitlines comprises buried bitlines formed within the substrate.

8. The device of claim 1, wherein:
the first transistors, the second transistors and the third transistors are formed on a substrate,
the voltage supply is coupled to a first buried power rail formed within the substrate, and
the ground is coupled to a second buried power rail formed within the substrate.

9. The device of claim 1, wherein:
the first transistors, the second transistors and the third transistors comprise P-type transistors and N-type transistors, and
the first transistors, the second transistors and the third transistors are formed with a P-type and N-type complementary field effect transistor (PN CFET) technology such that the P-type transistors are physically disposed on the N-type transistors or such that the N-type transistors are physically disposed on the P-type transistors.

10. A device comprising:
a plurality of transistors formed with a complementary field effect transistor (CFET) technology such that P-type transistors are physically disposed on N-type transistors or such that the N-type transistors are physically disposed on the P-type transistors,
wherein the transistors include first transistors arranged as cross-coupled inverters coupled between a voltage supply and ground;
wherein the transistors include second transistors arranged as passgates coupled between the cross-coupled inverters and bitlines, and
wherein the transistors include third transistors coupled in series between the voltage supply and a read bitline.

11. The device of claim 10, wherein:
the first transistors and the second transistors are configured to operate as a cross-coupled bitcell latch,
a gate of one of the third transistors is coupled to an output of the cross-coupled bitcell latch,
a gate of another of the third transistors is coupled to a read wordline, and
the third transistors are configured to provide a read port for the cross-coupled bitcell latch when the read wordline is activated.

12. The device of claim 11, wherein:
the first transistors, the second transistors and the third transistors are formed on a substrate, and
the read wordline comprises a buried read wordline formed within the substrate.

13. The device of claim 10, further comprising:
a write wordline coupled to gates of the second transistors,
the first transistors, the second transistors and the third transistors are formed on a substrate, and
the write wordline comprises a buried write wordline formed within the substrate.

14. The device of claim 10, wherein:
the first transistors, the second transistors and the third transistors are formed on a substrate, and
the bitlines comprises buried bitlines formed within the substrate.

15. The device of claim 10, wherein:
the first transistors, the second transistors and the third transistors are formed on a substrate,
the voltage supply is coupled to a first buried power rail formed within the substrate, and
the ground is coupled to a second buried power rail formed within the substrate.

16. A device comprising:
a plurality of transistors formed with a complementary field effect transistor (CFET) technology such that P-type transistors are physically disposed on N-type transistors or such that the N-type transistors are physically disposed on the P-type transistors,
wherein the transistors include first transistors arranged as cross-coupled inverters coupled between a voltage supply and ground;
wherein the transistors include second transistors arranged as first passgates coupled between the cross-coupled inverters and first bitlines; and
wherein the transistors include third transistors arranged as second passgates coupled between the cross-coupled inverters and second bitlines.

17. The device of claim 16, wherein:
the first transistors, second transistors and third transistors are configured to operate as a cross-coupled bitcell latch,
gates of the second transistors are coupled to a first wordline such that the second transistors are configured to provide a first read-write port for the cross-coupled bitcell latch when the first wordline is activated, and
gates of the third transistors are coupled to a second wordline such that the third transistors are configured to provide a second read-write port for the cross-coupled bitcell latch when the second wordline is activated.

18. The device of claim 17, wherein:
the first transistors, the second transistors and the third transistors are formed on a substrate,
the first write wordline comprises a first buried write wordline formed within the substrate, and
the second write wordline comprises a second buried write wordline formed within the substrate.

19. The device of claim 16, wherein:
the first transistors, the second transistors and the third transistors are formed on a substrate,
the first bitlines comprise first buried bitlines formed within the substrate, and
the second bitlines comprise second buried bitlines formed within the substrate.

20. The device of claim 16, wherein:
the first transistors, the second transistors and the third transistors are formed on a substrate,
the voltage supply is coupled to a first buried power rail formed within the substrate, and
the ground is coupled to a second buried power rail formed within the substrate.
